(19) United States
(12) Patent Application Publication
(10) Pub. No.: US 2025/0294797 A1
(43) Pub. Date: Sep. 18, 2025

(54) SEMICONDUCTOR DEVICE AND METHODS FOR FORMING THE SAME

(71) Applicant: Vanguard International Semiconductor Corporation, Hsinchu (TW)

(72) Inventors: Hsueh-Chun LIAO, Zhubei City (TW); Po-Heng LIN, New Taipei City (TW); Chia-Hao LEE, Zhubei City (TW); Che-Hua CHANG, Nantou City (TW); Chung-Ren LAO, Taichung City (TW); Chih-Cherng LIAO, Zhudong Township (TW); Chwen-Ming LIU, Hsinchu City (TW)

(73) Assignee: Vanguard International Semiconductor Corporation, Hsinchu (TW)

(21) Appl. No.: 18/739,888

(22) Filed: Jun. 11, 2024

(30) Foreign Application Priority Data
Mar. 15, 2024 (TW) 113109792

(51) Int. Cl. H01L 29/78; H01L 29/423; H01L 29/66

(52) U.S. Cl. CPC H10D 30/611; H10D 30/023; H10D 30/0285; H10D 30/65; H10D 64/514

(57) ABSTRACT

A semiconductor device includes a substrate, a first well region of the first conductivity type, and a second well region of the second conductivity type. The semiconductor device also includes a drain region, a source region, and a gate structure. The drain region of the first conductivity type is formed in the first well region and the source region of the first conductivity type is formed in the second well region. The gate structure on the substrate includes the first gate stack near the source region and the second gate stack near the drain region. The first gate stack includes the first gate dielectric layer and the first gate electrode layer. The second gate stack includes the second gate dielectric layer and the second gate electrode layer. The thickness of the first gate dielectric layer is different from the thickness of the second gate dielectric layer.

### CROSS REFERENCE TO RELATED APPLICATIONS

This Application claims priority of Taiwan Patent Application No. 113109792, filed on Mar. 15, 2024, the entirety of which is incorporated by reference herein.

### BACKGROUND

### Technical Field

The disclosure relates to a semiconductor device and methods for forming the same, and, in particular, it relates to a semiconductor device and its forming method that improves the figure of merit (FOM) of the semiconductor device.

### Description of the Related Art

In recent years, the development of semiconductor devices for use in computers, consumer electronics and other fields has progressed rapidly. Currently, semiconductor device technology has been widely accepted in Metal-Oxide-Semiconductor Field-Effect Transistor (MOSFET) products that have a high market share. Semiconductor devices are used in a variety of electronic applications, such as high-power devices, personal computers, cell phones, digital cameras, and other electronic devices. These semiconductor devices are typically fabricated by depositing insulating layers or dielectric layers, conductive layer materials, and semiconductor layer materials on a semiconductor substrate, followed by patterning the various material layers by using photolithography processes. Therefore, the circuit devices and components are formed on the semiconductor substrate.

Laterally diffused metal oxide semiconductor (LDMOS) devices, for example, are widely used in high-voltage power applications. LDMOS devices are suitable for transmitting high-frequency and high-power electrical signals. LDMOS devices have several important electronic characteristics, such as on-state resistance (Ron), capacitor charges, figure of merit (FOM), breakdown voltage, and leakage current. There is a performance trade-off between some of these electronic characteristics. Although existing semiconductor devices and methods for manufacturing the same have been adequate for their intended purposes, they have not been entirely satisfactory in all respects. Researchers continue to seek semiconductor devices with good performance in different electronic properties.

### BRIEF SUMMARY

Some embodiments of the present disclosure provide semiconductor devices. A semiconductor device of the embodiments includes a substrate, a first well region and a second well region in the substrate. The first well region has the first conductivity type. The second well region that is adjacent to the first well region has the second conductivity type. The semiconductor device further includes a drain region, a source region and a gate structure. The drain region extends downward from the top surface of the first well region into the first well region, and the drain region has the first conductivity type. The source region extends downward from the top surface of the second well region into the second well region, and the source region has the first conductivity type. The gate structure is formed on the substrate and positioned between the source region and the drain region. The gate structure includes a first gate stack near the source region and a second gate stack near the drain region. The first gate stack includes a first gate dielectric layer on the substrate and a first gate electrode layer on the first gate dielectric layer. The second gate stack includes a second gate dielectric layer on the substrate and a second gate electrode layer on the second gate dielectric layer. In addition, the thickness of the first gate dielectric layer is different from the thickness of the second gate dielectric layer.

Some embodiments of the present disclosure provide methods for forming a semiconductor device. A method for forming a semiconductor device includes providing a substrate; forming a first well region and a second well region in the substrate, wherein the first well region has the first conductivity type and the second well region has the second conductivity type; forming a drain region in the first well region and a source region in the second well region, wherein the drain region and the source region have the first conductivity type; and forming a gate structure over the substrate, wherein the gate structure is disposed between the source region and the drain region. The gate structure includes a first gate stack near the source region and a second gate stack near the drain region. The first gate stack includes a first gate dielectric layer on the substrate and a first gate electrode layer on the first gate dielectric layer. The second gate stack includes a second gate dielectric layer on the substrate and a second gate electrode layer on the second gate dielectric layer. In addition, the thickness of the first gate dielectric layer is different from the thickness of the second gate dielectric layer.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a semiconductor device at an intermediate manufacturing stage, in accordance with some embodiments of the present disclosure.

FIG. 2 is a schematic cross-sectional view of a gate structure GS of a semiconductor device, in accordance with some embodiments of the present disclosure.

FIG. 3A to FIG. 3L are schematic cross-sectional views of various intermediate stages of a method for manufacturing a gate structure GS of a semiconductor device, in accordance with some embodiments of the present disclosure.

FIG. 4 shows simulation results of the gate voltages in each of the semiconductor devices changing with the gate charge per unit area when the semiconductor devices of Comparative Example 1, Comparative Example 3 and Embodiment 1 are turned on.

FIG. 5 is a schematic cross-sectional view of a semiconductor device at an intermediate manufacturing stage, in accordance with some embodiments of the present disclosure.

FIG. 6 is a schematic cross-sectional view of a semiconductor device at an intermediate manufacturing stage, in accordance with some embodiments of the present disclosure.

FIG. 7 is a schematic cross-sectional view of a semiconductor device at an intermediate manufacturing stage, in accordance with some embodiments of the present disclosure.

FIG. 8 is a schematic cross-sectional view of a semiconductor device at an intermediate manufacturing stage, in accordance with some embodiments of the present disclosure.

### DETAILED DESCRIPTION OF THE INVENTION

The following description provides various embodiments, or examples, for implementing different features of the present disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numbers and/or letters in the various examples. This repetition is for the purpose of simplicity and clarity and does not in itself dictate a relationship between the various embodiments and/or configurations discussed.

In addition, spatially relative terms, such as “under”, “below”, “lower”, “above” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented, and the spatially relative descriptors used herein may likewise be interpreted accordingly.

Some embodiments are described below. Throughout the various views and illustrative embodiments, similar reference numbers are used to designate similar features/components. It should be understood that additional operations can be provided before, during, and after the method, and some of the operations can be replaced or eliminated for other embodiments of the method.

Embodiments provide semiconductor devices and methods for forming the same. In some embodiments, the gate structure of the semiconductor device includes two gate dielectric layers of different thicknesses. According to the configuration of the semiconductor device of the embodiment, the figure of merit (FOM) of the semiconductor device can be effectively improved without affecting the breakdown voltage and leakage current. The embodiments can be applied to metal-oxide-semiconductor (MOS) devices, such as laterally diffused MOS (LDMOS) devices. In addition, the embodiments can be applied to N-type LDMOS devices or P-type LDMOS devices.

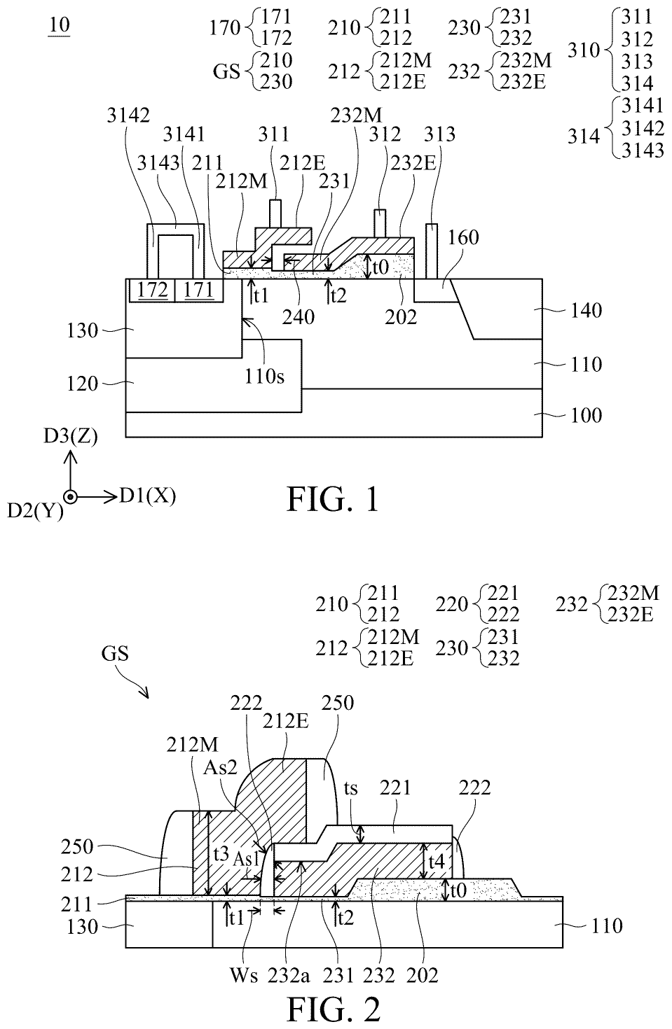

FIG. 1 is a schematic cross-sectional view of a semiconductor device at an intermediate manufacturing stage, in accordance with some embodiments of the present disclosure. In the embodiment shown in FIG. 1, a split-gate laterally diffused metal oxide semiconductor (split-gate LDMOS) structure is exemplified for illustrating the semiconductor device. However, the present disclosure is not limited to this exemplary structure.

According to some embodiments, as shown in FIG. 1, the semiconductor device 10 includes a substrate 100. Several doping regions, such as several well regions and heavily doped regions (functioning as the source region and the drain region), are formed in the substrate 100. In addition, the substrate 100 may also include (but not limited to) a buried layer (not shown). In some embodiments, the substrate 100 is a silicon substrate, an epitaxial silicon substrate, a silicon germanium substrate, a silicon carbide substrate, a silicon-on-insulator (SOI) substrate, or another suitable substrate.

In some embodiments, the substrate 100 includes a first well region 110 and a second well region 120 disposed adjacent to the first well region 110. The first well region 110 has the first conductivity type and the second well region 120 has the second conductivity type. The second conductivity type is opposite to the first conductivity type. In this embodiment, the first conductivity type is n-type and the second conductivity type is p-type. However, the present disclosure is not limited thereto. In some other embodiments, the first conductivity type can be p-type, and the second conductivity type can be n-type. In addition, the depth of the second well region 120 in the substrate 100 is, for example, slightly deeper than the depth of the first well region 110 in the substrate 100. In some embodiments, the second well region 120 is, for example (but not limited to), disposed around the periphery of the first well region 110, as viewed from the top of the substrate 100.

In some embodiments, a drain region 160 is formed in the first well region 110 of the semiconductor device 10. The drain region 160 extends downward from the top surface of the first well region 110 into the first well region 110. The drain region 160 is, for example, a first heavily doped region that has the first conductivity type (such as n-type). In this exemplary embodiment, the doping concentration of the drain region 160 is greater than the doping concentration of the first well region 110.

In some embodiments, a source region 170 is also formed in the substrate 100 of the semiconductor device 10. The semiconductor device 10 may also optionally include a third well region 130 that is formed in the second well region 120. The third well region 130 and the second well region 120 have the same conductivity type, such as the second conductivity type (e.g., p-type). In some embodiments, the source region 170 is formed in the third well region 130, and the source region 170 extends downward from the top surface of the third well region 130 into the third well region 130. The depth of the source region 170 in the substrate 100 does not exceed the depth of the third well region 130 in the substrate 100. Preferably, the doping concentration of the third well region 130 is greater than the doping concentration of the second well region 120. The third well region 130 may serve as a body region of the semiconductor device 10. Preferably, the doping concentration of the source region 170 is greater than the doping concentration of the third well region 130.

In addition, in some embodiments, the source region 170 that is formed in the third well region 130 includes two adjacent doped regions, such as the second heavily doped region 171 and the third heavily doped region 172. The second heavily doped region 171 and the third heavily doped region 172 are adjacent to each other. The second heavily doped region 171 is adjacent to the boundary between the first well region 110 and the third well region 130 (for example, the sidewall 110s of the first well region 110). In addition, the second heavily doped region 171 and the boundary (e.g., the sidewall 110s) are separated from each other by an appropriate lateral distance in the first direction D1. That is, the second heavily doped region 171 is not in physical contact with the first well region 110. In this exemplary embodiment, the second heavily doped region 171 and the third heavily doped region 172 extend in the second direction D2. In addition, the second heavily doped region 171 and the first well region 110 have the same conductivity type, such as the first conductivity type (e.g., n-type). The third heavily doped region 172 and the third well region 130 have the same conductivity type, such as the second conductivity type (e.g., p-type). In some embodiments, the doping concentration of the second heavily doped region 171 is greater than the doping concentration of the first well region 110, and the doping concentration of the third heavily doped region 172 is greater than the doping concentration of the third well region 130.

The semiconductor device 10 further includes several isolation structures 140, in accordance with some embodiments of the present disclosure. The isolation structures 140 are, for example, shallow trench isolations (STIs) that can be formed using an etching process and a deposition process, or field oxides (FOXs) that can be formed using a local oxidation of silicon (LOCOS) process. A portion of one of the isolation structures 140 is depicted in FIG. 1 as an example.

The semiconductor device 10 further includes a gate structure GS over the substrate 100, in accordance with some embodiments of the present disclosure. The gate structure GS is positioned between the drain region 160 and the source region 170. The gate structure GS includes a first gate stack 210 and a second gate stack 230. Each of the two gate structures includes a dielectric layer and a conductive layer stacked in the third direction D3. In this exemplary embodiment, the first gate stack 210 and the second gate stack 230 are two electrically independent gate stacks. During the operation of the semiconductor device, the first gate stack 210 and the second gate stack 230 may be connected to two independent voltage sources, thereby independently providing the first gate stack 210 and the second gate stack 230 with appropriate voltages. Accordingly, the device performance of the semiconductor device 10 can be improved. Specifically, in one exemplary embodiment, the on-resistance of the semiconductor device 10 can be reduced and the breakdown voltage can be increased by adjusting and supplying different voltages to the first gate stack 210 and the second gate stack 230 respectively.

In some embodiments, the first gate stack 210 is disposed across the first well region 110 and the third well region 130. The first gate stack 210 is disposed adjacent to the source region 170, such as adjacent to the second heavily doped region (such as n-type heavily doped region) 171. The first gate stack 210 includes the first gate dielectric layer 211 on the substrate 100 and the first gate electrode layer 212 on the first gate dielectric layer 211.

In some embodiments, the second gate stack 230 is formed on the first well region 110, and the second gate stack 230 is disposed adjacent to the drain region 160. The second gate stack 230 includes the second gate dielectric layer 231 on the substrate 100 and the second gate electrode layer 232 on the second gate dielectric layer 231. According to the present disclosure, the thickness t1 of the first gate dielectric layer 211 of the first gate stack 210 is different from the thickness t2 of the second gate dielectric layer 231 of the second gate stack 230.

In addition, in the embodiment shown in FIG. 1, the first gate electrode layer 212 of the first gate stack 210 extends above the second gate stack 230. A portion of the first gate electrode layer 212 overlaps with the second gate stack 230. For example, the first gate electrode layer 212 includes a main portion 212M and an extension portion 212E. The extension portion 212E is positioned above the second gate electrode layer 232 and partially overlaps with the second gate stack 230. It should be noted that the extension portion 212E is not in direct contact with the second gate electrode layer 232, in accordance with this exemplary embodiment.

In addition, in the embodiment shown in FIG. 1, the first gate stack 210 and the second gate stack 230 are electrically isolated from each other by the isolation structures or layers. For example, the first gate electrode layer 212 is separated from the second gate electrode layer 232. The first gate electrode layer 212 is electrically isolated from the second gate electrode layer 232 by filling an insulating material between the first gate electrode layer 212 and the second gate electrode layer 232. Specifically, as shown in FIG. 1, the bottom portion of the first gate electrode layer 212 (such as the main portion 212M) and the bottom portion of the second gate electrode layer 232 (such as the main portion 232M) are laterally separated from each other by a gap 240. The gap 240 is positioned above the first well region 110 and is filled with the insulating material.

In addition, in the embodiment shown in FIG. 1, the semiconductor device 10 further includes an insulating layer 202 disposed on the substrate 100. For example, the insulating layer 202 is formed on the first well region 110. In some embodiments, the second gate dielectric layer 231 connects the insulating layer 202, and the thickness t0 of the insulating layer 202 is greater than the thickness t2 of the second gate dielectric layer 231. In addition, a portion of the second gate electrode layer 232 is disposed across the insulating layer 202 to increase the vertical distance between the portion of the second gate electrode layer 232 and the substrate 100. The insulating layer 202 is, for example, a single-layer or a multilayer structure, and may include an oxide layer or another suitable insulating material. Specifically, as shown in FIG. 1, the second gate electrode layer 232 includes a main portion 232M and an extension portion 232E. The extension portion 232E is formed on the insulating layer 202 and partially overlaps with the insulating layer 202. The extension portion 232E is in direct contact with the insulating layer 202.

Next, the subsequent processes for forming other components of the semiconductor device 10 are performed. For example, an interlayer dielectric layer (not shown) is formed to cover the gate structure GS, several portions of the interlayer dielectric layer are removed to form the contact holes (not shown) and depositing a conductive material in the contact holes to form the contacts 310 to complete the fabrication of the semiconductor device 10. As shown in FIG. 1, the contacts 310 includes, for example, the contact 311 that is electrically connected to the first gate stack 210, the contact 312 that is electrically connected to the second gate stack 230, the contact 313 that is electrically connected to the drain region 160 and the contact 314 that is electrically connected to the source region 170. In this exemplary embodiment, the contact 314 includes, for example, a first portion 3141 in contact with the second heavily doped region 171, a second portion 3142 in contact with the third heavily doped region 172 and a third portion 3143 that connects the first portion 3141 and the second portion 3142. To simplify the description, the contacts 311, 312, 313 and 314 can be collectively referred to as the contacts 310.

In some embodiments, the contacts 310 each may be a single-layer structure or a multilayer structure. Examples of the conductive material for forming the contacts 310 include tungsten (W), aluminum (Al), copper (Cu), titanium (Ti), tantalum (Ta), titanium nitride (TiN), tantalum nitride (TaN), nickel silicide (NiSi), cobalt silicide (CoSi), tantalum carbide (TaC), tantalum silicon nitride (TaSiN), tantalum carbonitride (TaCN), titanium aluminide (TiAl), titanium aluminum nitride (TiAlN), another suitable metal, or a combination of the foregoing materials. In addition, in some embodiments, the conductive material can be formed by using a chemical vapor deposition (CVD) process, an atomic layer deposition (ALD) process, a physical vapor deposition (PVD) process, another suitable process, or a combination of the foregoing processes.

According to the above-mentioned descriptions, the gate structure GS of the embodiment is provided with two gate dielectric layers of different thicknesses. Accordingly, the figure of merit (FOM) of the semiconductor device can be effectively improved and the switching loss can be reduced without significantly affecting the breakdown voltage (BVoff) and the leakage current (Ioff) when the device is in the off operation state.

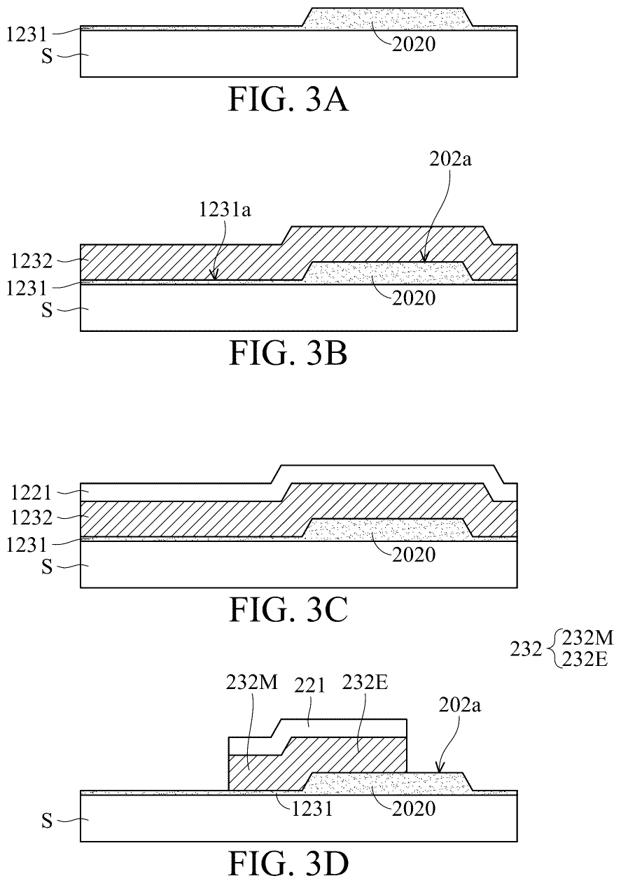

FIG. 2 is a schematic cross-sectional view of a gate structure GS of a semiconductor device, in accordance with some embodiments of the present disclosure. The features/components in FIG. 2 similar or identical to the features/components in FIG. 1 are designated with similar or the same reference numbers, and the details of those similar or the identical features/components are not repeated herein.

The semiconductor device 10 includes an isolation structure 220 to separate the first gate stack 210 from the second gate stack 230, in accordance with some embodiments of the present disclosure. As shown in FIG. 2, the isolation structure 220 may include an insulating cap layer 221 and a spacer 222. The insulating cap layer 221 is formed on the second gate stack 230 and covers the second gate electrode layer 232. The spacer 222 is formed on the sidewall of the second gate electrode layer 232 and the sidewall of the insulating cap layer 221. The main portion 212M of the first gate electrode layer 212 is in contact with the spacer 222. The extension portion 212E of the first gate electrode layer 212 is formed on the spacer 222 and the insulating cap layer 221. In this exemplary embodiment, the first gate electrode layer 212 not only covers the spacer 222 but also partially overlaps the underlying second gate electrode layer 232. The extended portion 212E of the first gate electrode layer 212 is in direct contact with the insulating cap layer 221, but is not in direct contact with the second gate electrode layer 232. Therefore, as shown in FIG. 1, the second gate electrode layer 232 is electrically isolated from the first gate electrode layer 212 by the spacer 222 and the insulating cap layer 221.

In addition, in some embodiments, after the first gate stack 210 is formed, the spacers 250 are also formed on the sidewalls of the first gate electrode layer 212. For example, One or more spacer materials are formed to cover one of the sidewalls of the main portion 212M and one of the sidewalls of the extension portion 212E to form the spacers 250. In addition, the spacer 250 also covers part of the insulating cap layer 221. The spacer 250 is, for example, a single-layer structure or a multilayer structure, and may include an oxide layer, a nitride layer, another suitable insulating material layer, or a combination of the foregoing layers.

The thickness ts of the insulating cap layer 221 (e.g., the thickness in the third direction D3 in FIG. 1) is greater than the bottom width Ws of the spacer 222 (e.g., the width in the first direction D1 in FIG. 1), in accordance with some embodiments of the present disclosure. According to the aforementioned descriptions, the bottom width Ws of the spacer 222 is equal to the gap 240 between the bottom portion of the first gate electrode layer 212 (e.g., the main portion 212M) and the bottom portion of the second gate electrode layer 232 (e.g., the main portion 232M). In this embodiment, the bottom width Ws of the spacer 222 is reduced as much as possible so as to reduce the on-resistance of the device. The insulating cap layer 221 has a sufficient thickness ts (for example, greater than the thickness of the spacer 222), so that the distance between the extension portion 212E of the first gate electrode layer 212 and the second gate electrode layer 232 can be increased. Thus, the parasitic capacitance between the extension portion 212E and the second gate electrode layer 232 can be reduced.

Specifically, in some embodiments, the spacer 222 has a narrower width at the top and increase in width toward the substrate 100. FIG. 2 illustrates an exemplary (but non-limiting) spacer 222. As shown in FIG. 2, the spacer 222 has a width As1 at the middle height thereof, and the spacer 222 has a width As2 at a portion that corresponds to the top edge of the second gate electrode layer 232 and at an angle of 45 degrees with the top surface 232a of the second gate electrode layer 232. In some embodiments, the thickness ts of the insulating cap layer 221 is greater than the width As2 of the spacer 222 and also greater than the width As1 of the spacer 222. In addition, in some embodiments, the width As1 of the spacer 222 may be substantially equal to the bottom width Ws of the spacer 222. In some embodiments, the width As2 of the spacer 222 may be substantially equal to the width As1 of the spacer 222.

In some embodiments, the bottom width Ws of the spacer 222 is, for example, but not limited to, in the range of about 0.02 micrometers (μm) to about 0.1 μm, or in another suitable range. The width As1 of the spacer 222 is, for example, but not limited to, in the range of about 0.02 μm to about 0.1 μm, or in another suitable range. In some embodiments, the width As2 of the spacer 222 is, for example, but not limited to, in the range of about 0.02 μm to about 0.1 μm, or in another suitable range. In some embodiments, the thickness ts of the insulating cap layer 221 is, for example, but not limited to, in the range of about 0.2 μm to about 2 μm, or in another suitable range.

In addition, the thickness t1 of the first gate dielectric layer 211 of the first gate stack 210 is different from the thickness t2 of the second gate dielectric layer 231 of the second gate stack 230, in accordance with some embodiments of the present disclosure. For example, the thickness t1 of the first gate dielectric layer 211 may be greater than the thickness t2 of the second gate dielectric layer 231. In some embodiments, the difference between the thickness t1 of the first gate dielectric layer 211 and the thickness t2 of the second gate dielectric layer 231 is, for example, but not limited to, at least 20 angstrom or more. However, the aforementioned numerical values are provided for exemplification, not intended to limit the thickness range of any gate dielectric layer of the present disclosure.

In addition, the thickness t3 of the first gate electrode layer 212 of the first gate stack 210 is different from the thickness t4 of the second gate electrode layer 232 of the second gate stack 230, in accordance with some embodiments of the present disclosure. For example, the thickness t3 of the first gate electrode layer 212 may be greater than the thickness t4 of the second gate electrode layer 232. In some embodiments, the thickness t3 of the first gate electrode layer 212 is, for example, about 0.2 μm, and the thickness t4 of the second gate electrode layer 232 is, for example, about 0.1 μm. However, the aforementioned numerical values are provided for exemplification and not used to limit the thickness range of the gate electrode layer of the present disclosure.

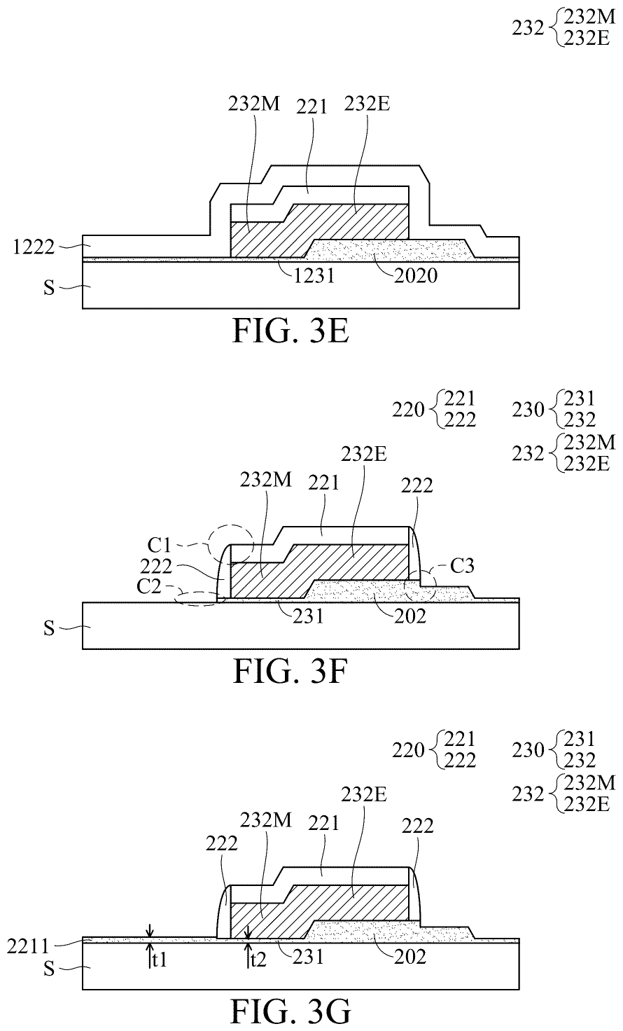

FIG. 3A to FIG. 3L are schematic cross-sectional views of various intermediate stages of a method for manufacturing a gate structure GS of a semiconductor device, in accordance with some embodiments of the present disclosure. Please also refer to FIG. 2. The features/components in FIG. 3A to FIG. 3L similar or identical to the features/components in FIG. 2 are designated with similar or the same reference numbers, and the details of those similar or the identical features/components can be referred to the related contents in the aforementioned descriptions. In addition, the regions (such as the first well region 110, the second well region 120, the third well region 130, the drain region 160 and the source region 170) in the substrate 100 are omitted in FIG. 3A to FIG. 3L, and the positions of those regions can be referred to the related contents of FIG. 1 aforementioned descriptions. To simplify the drawings and descriptions, those regions and the substrate 100 are collectively referred to as the substrate S for the sake of simplicity and clarity. In addition, it should be noted that the process depicted in FIG. 3A to FIG. 3L is provided for illustrative purposes, and the embodiments of the present invention are not intended to be limited thereto.

Referring to FIG. 3A, in some embodiments, an insulating layer 2020 can be formed on the substrate S by a deposition process, a lithographic patterning process and an etching process. A gate dielectric material layer 1231 is deposited on the substrate S and the insulating layer 2020. The thickness of the insulating layer 2020 is greater than the thickness of the gate dielectric material layer 1231. In this exemplary embodiment, the insulating layer 2020 and the gate dielectric material layer 1231 include the same material, such as silicon oxide. Therefore, the interface between the gate dielectric material layer 1231 and the insulating layer 2020 can be omitted in FIG. 3A to FIG. 3L.

Referring to FIG. 3B, in some embodiments, a gate electrode material layer 1232 is deposited over the gate dielectric material layer 1231 to cover the gate dielectric material layer 1231 and the top surface 202a of the insulating layer 2020. In some embodiments, the gate electrode material layer 1232 includes, for example, polysilicon or another suitable material. The gate electrode material layer 1232 can be formed by a physical vapor deposition (PVD) process, a chemical vapor deposition (CVD) process, or another process for deposition. In some embodiments, the thickness of the gate electrode material layer 1232 is, for example, but not limited to, in the range of 400 angstroms to 1800 angstroms.

Next, referring to FIG. 3C, in some embodiments, a capping material layer 1221 is deposited over the gate electrode material layer 1232. The capping material layer 1221 includes, for example, oxide or another suitable insulating material. The capping material layer 1221 can be formed by chemical vapor deposition (CVD), atomic layer deposition (ALD), physical vapor deposition (PVD), another suitable process, or a combination of the aforementioned processes. In addition, the thickness of the capping material layer 1221 is, for example, but not limited to, less than the thickness of the gate electrode material layer 1232. In some embodiments, the thickness of the capping material layer 1221 is, for example, but not limited to, in the range of 200 angstroms to 1200 angstroms.

Next, referring to the FIG. 3D, in some embodiments, the above-mentioned capping material layer 1221 and the gate electrode material layer 1232 are patterned by appropriate lithography processes and etching processes. Referring to the above-mentioned embodiments, FIG. 1 and FIG. 2, after the capping material layer 1221 and the gate electrode material layer 1232 are patterned by appropriate processes, the insulating cap layer 221 and the gate electrode material layer 1232 as shown in FIG. 1 and FIG. 2 can be formed respectively. The second gate electrode layer 232 includes a main portion 232M and an extension portion 232E that is formed on the insulating layer 2020, in accordance with some embodiments of the present disclosure.

Next, spacers (such as the spacers 222 depicted in FIG. 1 and FIG. 2 in the above-mentioned embodiment) are formed on the sidewalls of the insulating cap layer 221 and the sidewalls of the second gate electrode layer 232, as shown in FIG. 3E to FIG. 3G. Details are described below.

As shown in FIG. 3E, in some embodiments, a spacer material layer 1222 is deposited on the insulating cap layer 221 and the second gate electrode layer 232 to cover the insulating cap layer 221, the second gate electrode layer 232, the exposed portion of the dielectric material layer 1231 and the exposed portion of the insulating layer 2020. The spacer material layer 1222 includes, for example, an oxide or another suitable insulating material. The spacer material layer 1222 can be formed by chemical vapor deposition (CVD), atomic layer deposition (ALD), physical vapor deposition (PVD), another suitable process, or a combination of the foregoing processes. The spacer material layer 1222 and the underlying insulating cap layer 221 may include the same material or different materials. In addition, the thickness of the spacer material layer 1222 may (but is not limited to) be substantially equal to the thickness of the insulating cap layer 221. In some embodiments, the thickness of the spacer material layer 1222 is, for example, but not limited to, in the range of 200 angstroms to 1200 angstroms.

Next, referring to FIG. 3F, in some embodiments, portions of the spacer material layer 1222 are removed to form the spacers 222 on the sidewalls of the insulating cap layer 221 and the sidewalls of the second gate electrode layer 232. During the step of removing the portions of the spacer material layer 1222, the portion of the gate dielectric material layer 1231 that is positioned outside the spacers 222 is also removed. The remaining portion of the gate dielectric material layer 1231 is referred to as the second gate dielectric layer 231 shown in FIG. 1 and FIG. 2, in accordance with some embodiments described above. After the step of removing the portions of the spacer material layer 1222, the top surface of the insulating cap layer 221 and a portion of the top surface of the substrate 100 are exposed. In addition, the aforementioned removal process may include, for example, a dry etching process, a wet etching process, a plasma etching process, a reactive ion etching process, another suitable process, or a combination of the foregoing processes.

In some embodiments, portions of the spacer material layer 1222 can be removed by a combination of a dry etching process (that is, the etching stops by setting an appropriate etching time) and a wet etching process (that is, the etching stops by setting an appropriate etching thickness). It should be noted that after the removal process, the insulating cap layer 221 has a uniform thickness, and the intersection between the top of the spacer 222 and the insulating cap layer 221 (such as the circled region C1 in FIG. 3F) is still thick enough to cover the sidewalls of the second gate electrode layer 232. In addition, when the portions of the gate dielectric material layer 1231 that are uncovered by the spacers 222 are removed by etching, excessive damage to the substrate 100 (that include silicon material) (occurred at the position such as the circled region C2 in FIG. 3F) is avoided. In addition, in some embodiments, over-etching may occur at the insulating layer 2020 (such as the circled region C3 in FIG. 3F), resulting in a portion of the insulating layer 2020 being thinned (in the following description, the remaining portion of the insulating layer 2020 is referred to as the insulating layer 202).

Next, referring to FIG. 3G, in some embodiments, another gate dielectric material layer 2211 is formed on the substrate S. The gate dielectric material layer 2211 can be referred to as the first gate dielectric layer 211 in FIG. 1 and FIG. 2, as described in the above-mentioned embodiments. In some embodiments, the thickness t1 of the gate dielectric material layer 2211 is greater than the thickness t2 of the second gate dielectric layer 231. Details of the applicable materials and manufacturing method of the gate dielectric material layer 2211 shown in FIG. 3G are essentially the same as what have been discussed referring to the gate dielectric material layer 1231 (FIG. 3A), and are not repeated herein.

Next, referring to FIG. 3H, in some embodiments, another gate electrode material layer 2212 is deposited over the gate dielectric material layer 2211 to cover the structure shown in FIG. 3G. For example, the gate electrode material layer 2212 covers the gate dielectric material layer 2211, the spacers 222, the insulating cap layer 221 and the insulating layer 202. This gate electrode material layer 2212 can be patterned to form the first gate electrode layer 212 as shown in the above-mentioned embodiments of FIG. 1 and FIG. 2 after subsequent fabrication. In addition, in some embodiments, the thickness t3 of the gate electrode material layer 2212 may be greater than the thickness t4 of the second gate electrode layer 232. Details of the applicable materials and manufacturing method of the gate electrode material layer 2212 shown in FIG. 3H are essentially the same as what have been discussed referring to the gate electrode material layer 1232 (FIG. 3B), and are not repeated herein.

Next, referring to FIG. 3I, in some embodiments, the gate electrode material layer 2212 is patterned by appropriate lithography processes and etching processes. Referring to the descriptions, FIG. 1 and FIG. 2 in the above-mentioned embodiments, the gate electrode material layer 2212 can be patterned to form the first gate electrode layer 212 (as shown in FIG. 1 and FIG. 2). The first gate electrode layer 212 includes the main portion 212M that is positioned on the gate dielectric material layer 2211 and the extension portion 212E that is positioned on the spacer 222 and the insulating cap layer 221.

As shown in FIG. 3I, in some embodiments, the extension portion 212E of the first gate electrode layer 212 has an overlapping area Ao with the second gate electrode layer 232 that is disposed below the insulating cap layer 221. In other words, a vertical projection area of the first gate electrode layer 212 on the substrate S partially overlaps with a vertical projection area of the second gate electrode layer 232 on the substrate S. Preferably, in one embodiment, the extension portion 212E of the first gate electrode layer 212 does not overlap the insulating layer 202.

In addition, as shown in FIG. 3I, in some embodiments, the second gate electrode layer 232 is lower than the extension portion 212E of the first gate electrode layer 212. After the first gate electrode layer 212 is formed, the distance between the bottom surface of the first gate electrode layer 212 and the bottom surface of the second gate electrode layer 232 (that is equal to the bottom width Ws of the spacer 222) is less than the distance between the bottom surface of the extension portion 212E of the first gate electrode layer 212 and the top surface of the main portion 232M of the second gate electrode layer 232 (that is equal to the thickness ts of the insulating cap layer 221) (i.e., Ws<ts). In addition, as shown in FIG. 3I, in some embodiments, a recess 212R may be formed between the sidewall of the extension portion 212E of the first gate electrode layer 212 and the top surface of the insulating cap layer 221.

Next, referring to FIG. 3J to FIG. 3L, in some embodiments, the spacers 250 are formed on the sidewalls of the first gate electrode layer 212.

In some embodiments, as shown in FIG. 3J, a first silicon oxide layer 2510 can be conformally deposited on and cover an underlying structure that is formed in FIG. 3I. In this exemplary embodiment, the first silicon oxide layer 2510 fills the recess 212R. Next, referring to FIG. 3K, a silicon nitride layer 2520 can be conformally deposited on the first silicon oxide layer 2510, and a second silicon oxide layer 2530 can be conformally deposited on the silicon nitride layer 2520. Next, referring to FIG. 3L, in some embodiments, the second silicon oxide layer 2530, the silicon nitride layer 2520 and the first silicon oxide layer 2510 are patterned by appropriate lithography processes and etching processes. The remaining portions of the second silicon oxide layer 253, silicon nitride layer 252 and first silicon oxide layer 251 may be collectively referred to as spacers 250. As shown in FIG. 3L, the spacers 250 covers the sidewall of the first gate electrode layer 212 and a portion of the top surface of the insulating cap layer 221. The spacers 250 also fills the recess 212R between the extension portion 212E and the insulating cap layer 221.

Several relative electrical simulations are conducted for investigate the electrical characteristics of the semiconductor devices that have different configuration of the gate structure. Table 1 shows some of the simulation experiment results. According to the simulation results, it can be proved that the gate structure provided in the embodiments do effectively improve the electrical performance of the semiconductor device, especially the figure of merit (FOM) of the semiconductor device. The simulation experiments are described as follows.

According to the simulation results in Table 1, four different semiconductor devices that have different gate structures are investigated for electrical simulations. The gate voltage (Vg) of the semiconductor devices is 3.3V. Those semiconductor devices are respectively referred to as semiconductor devices of Comparative Example 1, Comparative Example 2, Comparative Example 3 and Embodiment 1, and their structures are briefly described as follows.

The semiconductor device of Comparative Example 1 is a conventional LDMOS device. The gate structure includes a gate dielectric layer and a gate electrode layer, wherein the thickness of the gate dielectric layer is expressed as T_{GOX} Angstroms (Å). The pitch of the semiconductor device is expressed as P micrometers.

The semiconductor device of Comparative Example 2 is a conventional LDMOS device. The gate structure includes a gate dielectric layer and a gate electrode layer, wherein the thickness of the gate dielectric layer is expressed as T_{GOX} Angstroms. Compared to the semiconductor device of Comparative Example 1, the pitch of the semiconductor device of Comparative Example 2 is reduced by 25% and is expressed as 75%*P micrometers.

The semiconductor device of Comparative Example 3 is a conventional split-gate LDMOS device. The gate dielectric layers of two gate stacks have the same thickness. The thicknesses of the gate dielectric layers of the gate stacks are both expressed as T_{GOX-} 20 Angstroms. In addition, compared to the semiconductor device of Comparative Example 1, the pitch of the semiconductor device of Comparative Example 3 is reduced by 40% and is expressed as 60%*P micrometers. In addition, the insulation gap between the two gate stacks is expressed as Ws micrometers, wherein 50%*Ws<Ws<150%*Ws.

The semiconductor device of Embodiment 1 includes two gate stacks. As shown in FIG. 1, the gate dielectric layers of two gate stacks have different thicknesses. The thickness of the first gate dielectric layer 211 is expressed as T_{GOX} Angstroms (Å), and the thickness of the second gate dielectric layer 231 is expressed as T_{GOX-} 20 Angstroms Å. In addition, compared to the semiconductor device of Comparative Example 1, the pitch of the semiconductor device of Embodiment 1 is reduced by 40% and is expressed as 60%*P micrometers. In addition, the insulation gap (such as the width As1 and/or the bottom width Ws of the spacer 222) between the two gate stacks is expressed as Ws micrometers, wherein 50%*Ws<Ws<150%*Ws.

In this simulation experiments, several related electrical simulation tests were conducted using the semiconductor devices of the above-mentioned Comparative Examples and Embodiment 1 shown in FIG. 1. Table 1 shows the relevant dimensions and electrical simulation results of those semiconductor devices under the same gate voltage (Vg) of about 3.3V. In addition, the simulation is analyzed with a Technical Computer Aided Design (TCAD) system.

TABLE 1

| | | Comparative | | Comparative | | Comparative | | | |
|---|---|---|---|---|---|---|---|---|---|
| Parameters | | Example 1 | | Example 2 | | Example 3 | | Embodiment 1 | |
| Extra mask | | No | | Yes | | Yes | | Yes | |
| Gate voltage | | 3.3 V | | 3.3 V | | 3.3 V | | 3.3 V | |
| (Vg)(V) | | | | | | | | | |
| Thickness | | T_{GOX} | | T_{GOX} | | T_{GOX}-20 | | T_{GOX}, (T_{GOX}-20) | |
| of the gate | | | | | | | | | |
| dielectric | | | | | | | | | |
| layer (Å) | | | | | | | | | |
| Pitch (μm) | | P | | 75%*P | | 60%*P | | 60%*P | |
| Insulation gap | | NA | | NA | | Ws | | Ws | |
| or bottom width | | | | | | | | | |
| of the spacer (μm) | | | | | | | | | |
| Data | | Silicon | TCAD | TCAD | Difference | TCAD | Difference | TCAD | Difference |
| | | substrate | | | (%) | | (%) | | (%) |
| Threshold | | 1.05 | 1.06 | 1.04 | −1.9% | 1.08 | 1.9% | 1.08 | 1.9% |
| voltage | | | | | | | | | |
| (Vth)(V) | | | | | | | | | |
| Ron, sp (mΩ- | | 5.20 | 5.3 | 3.22 | 39.2% | 2.59 | −51.1% | 2.81 | −47.0% |
| mm²) | | | | | | | | | |
| Ron (mΩ) | | 145.3 | 131.8 | 119.7 | −9.2% | 117.6 | −10.8% | 128 | −2.8% |
| Breakdown | | 22 | 21.4 | 21.3 | −0.5% | 21.4 | 0.0% | 20.9 | −2.3% |
| voltage | | | | | | | | | |
| (BVoff)(V) | | | | | | | | | |
| Leakage current | | — | — | 0.11 | — | 0.4 | — | 0.5 | — |
| (Ioff)(pA) | | | | | | | | | |
| Gate charges | | 0.214 | 0.173 | 0.142 | −18.2% | 0.101 | −41.8% | 0.092 | −46.7% |
| (Qg)(nC) | | | | | | | | | |
| Gate-to-drain | | 0.110 | 0.050 | 0.056 | 12.5% | 0.021 | −58% | 0.016 | −66.8% |
| charges (Qgd) | | | | | | | | | |
| (nC) | | | | | | | | | |
| FOM | *(1) | 31.1 | 22.8 | 17 | −25.4% | 11.88 | −47.9% | 11.78 | −48.3% |
| (mΩ- | *(2) | 16.0 | 7.3 | 6.7 | −9.1% | 2.5 | −66.6% | 2.1 | −71.4% |
| nC) | | | | | | | | | |

[Note]
*(1): Ron*Qg;
*(2): Ron*Qgd

According to the simulation results, compared to the pitch of the conventional LDMOS device of Comparative Example 1, the pitch of the split-gate semiconductor device of the embodiment is reduced by about 40%. Therefore, more semiconductor units of the embodiments can be arranged in the same area.

According to the simulation results in Table 1, compared to the on-resistance (Ron) of the semiconductor device of Comparative Example 3, the on-resistance (Ron) of the semiconductor device of Embodiment 1 is slight increased. However, compared to the on-resistances (Ron) of the semiconductor devices of Comparative Examples 1 and 2, the on-resistance (Ron) of the semiconductor device of Embodiment 1 is significantly decreased.

In addition, figure of merit (FOM) are generally used to evaluate the performance of the semiconductor devices. FOM is the product of the charges (Qg; the required charges when the capacitor is charged and discharged) and the on-resistance (Ron). Compared to the FOM of the conventional LDMOS device of Comparative Example 1 (Ron*Qg=22.8 mΩ-nC), the FOM of the semiconductor device of Embodiment 1 (Ron*Qg=11.78 mΩ-nC) is significantly improved by about 48.3%. Compared to the FOM of the semiconductor device of Comparative Example 3 (Ron*Qg=11.88 mΩ-nC), the FOM of the semiconductor device of Embodiment 1 is also improved.

In addition, Table 1 also shows the product of the charges between gate and drain (Qgd) and the on-resistance (Ron). The smaller Qgd is, the faster the charging and discharging speed of the gate-to-drain capacitance of the device is. Compared to the conventional LDMOS device of Comparative Example 1, the FOM (2.1 mΩ-nC) that is the product of Qgd and the on-resistance (Ron) of the semiconductor device of Embodiment 1 can be greatly improved by about 71.4%. Compared to the semiconductor device of Comparative Example 3, the FOM that is the product of Qgd and the on-resistance (Ron) of the semiconductor device of Embodiment 1 (that have the gate dielectric layers with different thicknesses) is greatly decreased. Therefore, the semiconductor device of Embodiment 1 does significantly improve the electrical characteristics of the semiconductor device.

In addition, the semiconductor device of Comparative Example 3 is a split-gate semiconductor device. By applying different voltages to the first gate electrode and the second gate electrode, the semiconductor device of Comparative Example 3 can achieve a breakdown voltage (BVoff) that is very close to the breakdown voltage of the semiconductor device of Comparative Example 2. Although the breakdown voltage (BVoff) of the semiconductor device of Embodiment 1 is slightly lower than the breakdown voltage of the semiconductor device of Comparative Example 3, the degree of decrease is very small. Compared to the FOMs of the semiconductor devices of Comparative Example 1 and Comparative Example 2, the FOM of the semiconductor device of Embodiment 1 is greatly improved. In addition, compared to the FOM of the semiconductor device of Comparative Example 3, the FOM of the semiconductor device of Embodiment 1 is still improved.

Therefore, according to the simulation experiment results as provided above, the FOM of the conventional LDMOS device may have a certain degree of improvement. For example, compared to the semiconductor device of Comparative Example 1, the Qg-related FOM (i.e. Qg*Ron) of the semiconductor device of Comparative Example 2 is improved by about 25.4%, and the Qgd-related FOM (i.e. Qgd*Ron) of the semiconductor device of Comparative Example 2 is improved by approximately 9.1%. In addition, compared to the semiconductor device of Comparative Example 1, the Qg-related FOM (i.e. Qg*Ron) of the semiconductor device of Comparative Example 3 is improved by about 47.9%, and the Qgd-related FOM (i.e. Qgd*Ron) of the semiconductor device of Comparative Example 3 is improved by approximately 66.6%. However, by arranging the gate dielectric layers that have different thicknesses in different gate stacks, the Qg-related FOM (i.e. Qg*Ron) of the semiconductor device of Embodiment 1 can be greatly improved by about 48.3%, and the Qgd-related FOM (i.e. Qgd*Ron) can be greatly improved by about 71.4%.

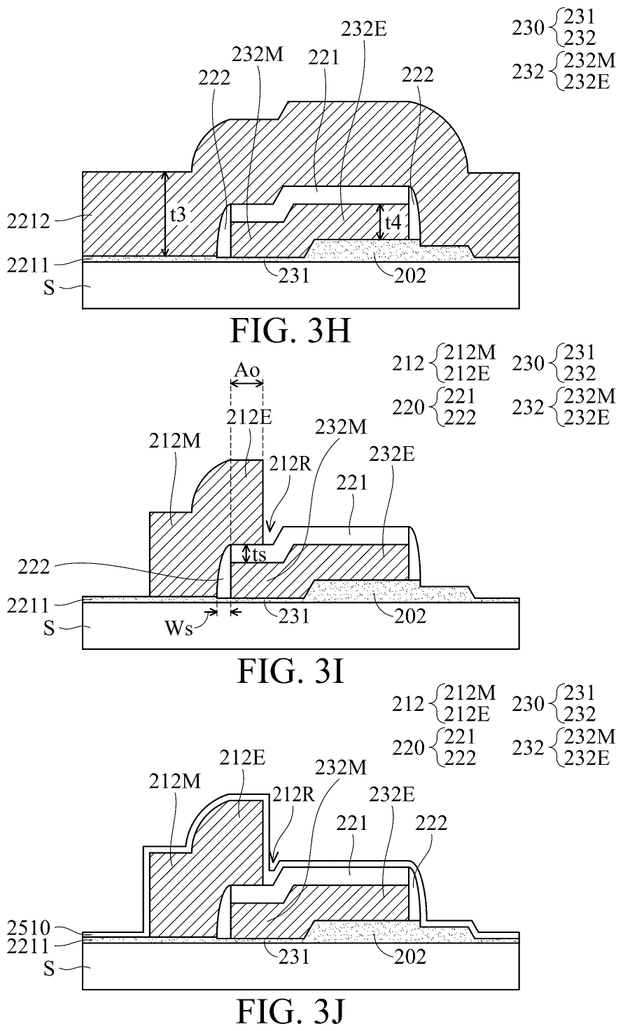

FIG. 4 shows simulation results of the gate voltages (Vg; V) in each of the semiconductor devices changing with the gate charge per unit area (nC/mm2) when the semiconductor devices of Comparative Example 1, Comparative Example 3 and Embodiment 1 are turned on. In FIG. 4, curve (I), curve (II) and curve (III) represent the simulation results of the semiconductor devices of Comparative Example 1, Comparative Example 3 and Embodiment 1, respectively. Each of the curves (I) to (III) indicates the distribution of the charges when the gate dielectric layer is fully charged and the semiconductor device is turned on. The middle section of the curve is the slow-rising section, which corresponds to the charges per unit area when the capacitor between the gate and the drain is charged. As shown in Table 1, compared to the conventional LDMOS device of Comparative Example 1, the gate-to-drain charges of the semiconductor device of Comparative Example 3 can be significantly reduced by about 58%, and the gate-to-drain charges of the semiconductor device of Embodiment 1 can even be greatly reduced by about 66.8%. In addition, as shown in FIG. 4, compared to the curves (I) and (II), the slow-rising section (Qgd section) in the middle of the curve (III) of the semiconductor device of Embodiment 1 is the shortest, which indicates that the semiconductor device of Embodiment 1 has the fastest speed to completely charge the capacitor between the gate and the drain. Accordingly, the semiconductor device of Embodiment 1 has a faster switching speed and can reduce power consumption when the semiconductor device switches between the on state and the off state.

According to the foregoing descriptions, the gate structure GS provided in the embodiments can effectively improve the figure of merit (FOM) of the semiconductor device and reduce the switching power loss of the semiconductor device by providing two gate dielectric layers with different thicknesses. In addition, the breakdown voltage (BVoff) and leakage current (Ioff) of the semiconductor device of the embodiments will not be significantly affected when the semiconductor device is in the off state.

It should be noted that the gate structure GS of the present disclosure is not limited to arrangement of the components of the gate structure shown in FIG. 1 and FIG. 2. The following presents component arrangement of the gate structure applicable to some, but not all, of the embodiments of the present disclosure.

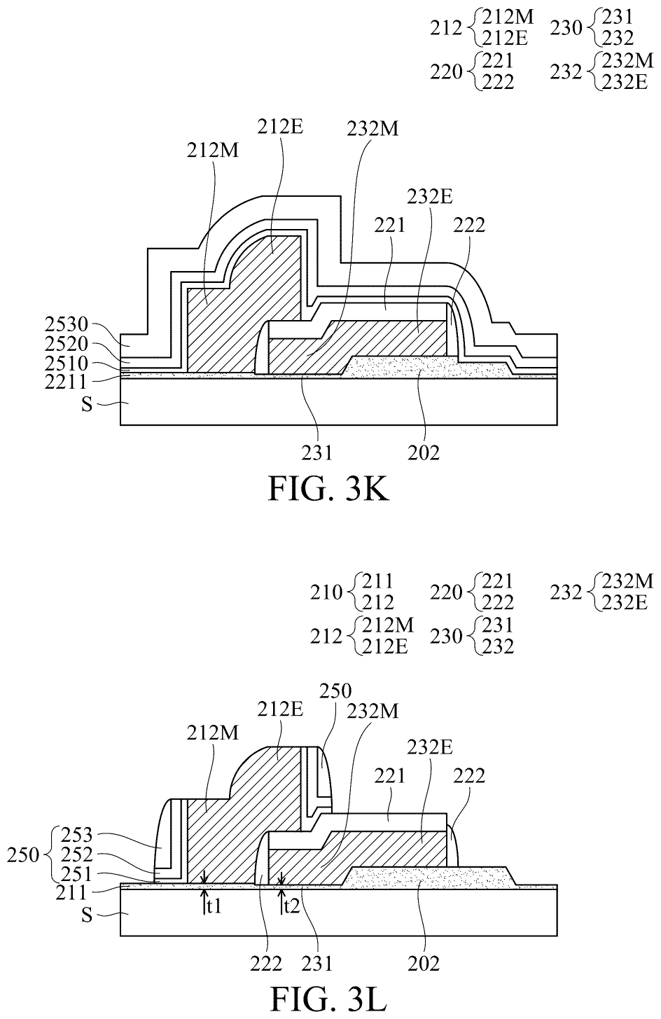

FIG. 5 is a schematic cross-sectional view of a semiconductor device at an intermediate manufacturing stage, in accordance with some embodiments of the present disclosure. The features/components in FIG. 5 similar or identical to the features/components in FIG. 1 are designated with similar or the same reference numbers, and the details of those similar or the identical features/components are not repeated herein. The difference between the semiconductor device 50 in FIG. 5 and the semiconductor device 10 in FIG. 1 is the position of the extension portion 212E of the first gate electrode layer 212.

In the semiconductor device 50 shown in FIG. 5, the substrate 100 includes the first well region 110 (for example, n-type), the second well region 120 (for example, p-type), the third well region 130 (for example, p-type), the isolation structure 140, the drain region 160 (for example, n-type) and the source region 170 (for example, n-type). The semiconductor device 50 further includes a gate structure GS over the substrate 100. The gate structure GS is formed between the drain region 160 and the source region 170. The gate structure GS includes the first gate stack 210 and the second gate stack 230 that are electrically independent from each other. The first gate stack 210 is disposed over the first well region 110 and the third well region 130. In addition, the first gate stack 210 is disposed adjacent to the source region 170. The second gate stack 230 is disposed over the first well region 110 and adjacent to the drain region 160. The first gate stack 210 includes the first gate dielectric layer 211 and the first gate electrode layer 212. The first gate electrode layer 212 also includes a main portion 212M and an extension portion 212E. In addition, the second gate stack 230 includes the second gate dielectric layer 231 and the second gate electrode layer 232. The second gate electrode layer 232 also includes a main portion 232M and an extension portion 232E. The extension portion 232E extends to the position over the insulating layer 202. In addition, the thickness t1 of the first gate dielectric layer 211 is different from the thickness t2 of the second gate dielectric layer 231. For example, the thickness t1 of the first gate dielectric layer 211 is greater than the thickness t2 of the second gate dielectric layer 231. By providing gate dielectric layers with different thicknesses, the figure of merit (FOM) of the semiconductor device 50 can be effectively improved, and the switching power loss of the semiconductor device 50 can be reduced without affecting the breakdown voltage and leakage current when the semiconductor device 50 is turned off.

In addition, the gap 240 between the first gate electrode layer 212 and the second gate electrode layer 232 is also filled with one of more insulating materials, such as spacers (not shown in FIG. 5. Please refer to the spacer 222 in FIG. 1 and FIG. 2) to electrically isolate the first gate stack 210 and the second gate stack 230. In this exemplary embodiment, the extension portion 212E of the first gate electrode layer 212 extends to the position over the insulating material in the gap 240, such as the position over the spacer 222 of FIG. 1 and FIG. 2. However, the extension portion 212E does not extend to the position over the second gate electrode layer 232. Specifically, the edge 212S of the extension portion 212E of the first gate electrode layer 212 is substantially aligned with the edge 232S of the main portion 232M of the second gate electrode layer 232.

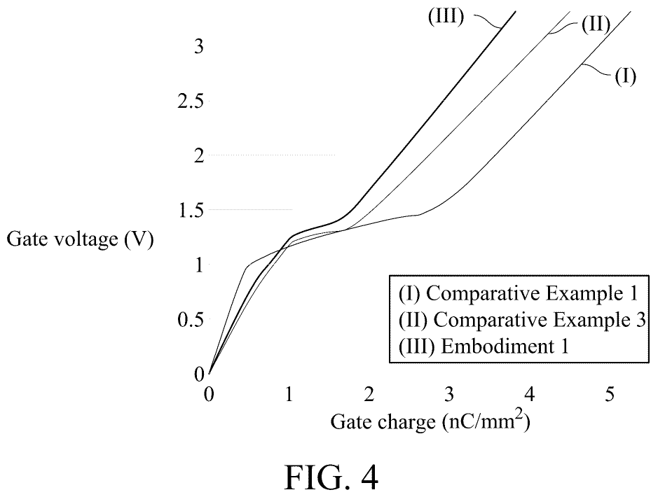

Details of the configurations, the materials and the manufacturing methods of the components in FIG. 5 can be referred to those in the above-mentioned descriptions referring to FIG. 1, FIG. 2 and FIG. 3A to FIG. 3L. Those contents will not be repeated herein. In addition, although the process shown in FIG. 3A to FIG. 3L exemplifies that the second gate stack 230 is formed before forming the first gate stack 210, the present disclosure is not limited thereto. In the manufacturing process for forming the semiconductor device of some embodiments, such as the semiconductor device of FIG. 5 or another semiconductor device (such as the semiconductor device of FIG. 6), the first gate stack 210 can be formed before forming the second gate stack 230. The present disclosure has not particular limitation to the sequence for forming the first gate stack 210 and the second gate stack 230 of the gate structure GS of the embodiments.

Accordingly, in the semiconductor device 50 of the embodiment shown in FIG. 5, the first gate electrode layer 212 of the first gate stack 210 has an extension 212E, but the first gate electrode layer 212 and the second gate electrode layer 232 of the second gate stack 230 do not overlap.

FIG. 6 is a schematic cross-sectional view of a semiconductor device at an intermediate manufacturing stage, in accordance with some embodiments of the present disclosure. The features/components in FIG. 6 similar or identical to the features/components in FIG. 1 are designated with similar or the same reference numbers, and the details of those similar or the identical features/components are not repeated herein. The difference between the semiconductor device 60 in FIG. 6 and the semiconductor device 10 in FIG. 1 is the configurations of the first gate stack 210 and the second gate stack 230.

In the semiconductor device 60 shown in FIG. 6, the substrate 100 includes the first well region 110 (for example, n-type), the second well region 120 (for example, p-type), the third well region 130 (for example, p-type), the isolation structure 140, the drain region 160 (for example, n-type) and the source region 170 (for example, n-type). The semiconductor device 60 further includes a gate structure GS over the substrate 100. The gate structure GS is formed between the drain region 160 and the source region 170. The gate structure GS includes the first gate stack 210 and the second gate stack 230 that are electrically independent from each other. The first gate stack 210 is disposed over the first well region 110 and the third well region 130. In addition, the first gate stack 210 is disposed adjacent to the source region 170. The second gate stack 230 is disposed over the first well region 110 and adjacent to the drain region 160. The first gate stack 210 includes the first gate dielectric layer 211 and the first gate electrode layer 212. Different from the semiconductor devices in the previous embodiments, the first gate electrode layer 212 of the semiconductor device 60 in FIG. 6 does not have a raised extension portion. In addition, the second gate stack 230 includes the second gate dielectric layer 231 and the second gate electrode layer 232. The second gate electrode layer 232 also includes a main portion 232M and an extension portion 232E. The extension portion 232E extends to the position over the insulating layer 202. In addition, the thickness t1 of the first gate dielectric layer 211 is different from the thickness t2 of the second gate dielectric layer 231. For example, the thickness t1 of the first gate dielectric layer 211 is greater than the thickness t2 of the second gate dielectric layer 231. By providing gate dielectric layers with different thicknesses, the figure of merit (FOM) of the semiconductor device 60 can be effectively improved, and the switching power loss of the semiconductor device 60 can be reduced without affecting the breakdown voltage and leakage current when the semiconductor device 60 is turned off.

In addition, there is a gap 240 between the edge 212S of the first gate electrode layer 212 and the edge 232S of the second gate electrode layer 232. The gap 240 is also filled with one of more insulating materials, such as spacers (not shown in FIG. 6, but can be referred to the spacer 222 in FIG. 1 and FIG. 2) to electrically isolate the first gate stack 210 and the second gate stack 230. Details of the configurations, the materials and the manufacturing methods of the components in FIG. 6 can be referred to those in the above-mentioned descriptions referring to FIG. 1, FIG. 2 and FIG. 3A to FIG. 3L. Those contents will not be repeated herein.

Accordingly, in the semiconductor device 60 of the embodiment shown in FIG. 6, the first gate electrode layer 212 of the first gate stack 210 does not have an extension, so that the first gate electrode layer 212 of the first gate stack 210 and the second gate electrode layer 232 of the second gate stack 230 do not overlap.

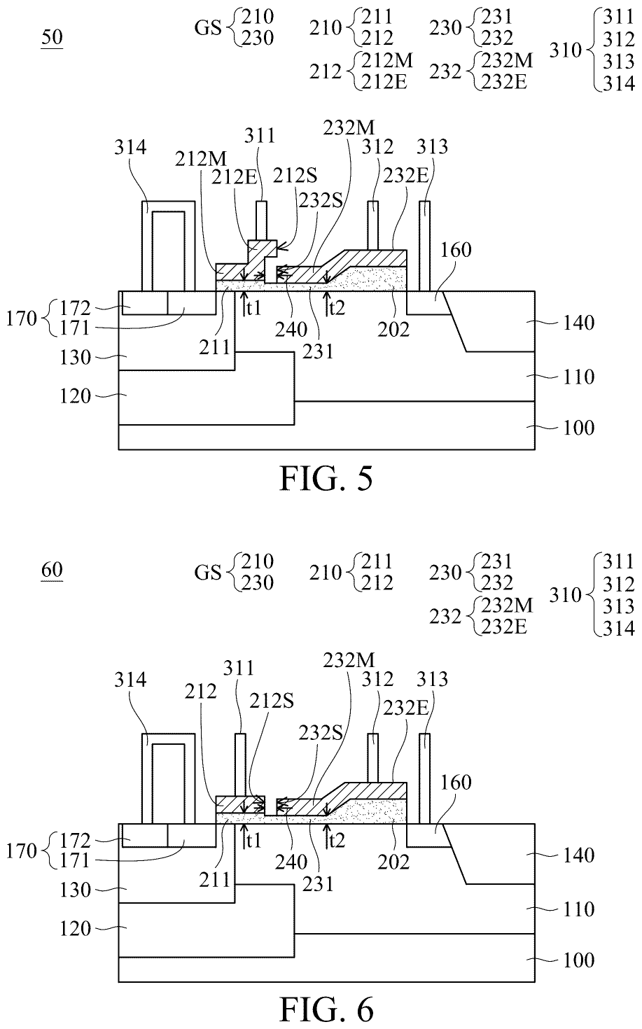

FIG. 7 is a schematic cross-sectional view of a semiconductor device at an intermediate manufacturing stage, in accordance with some embodiments of the present disclosure. The features/components in FIG. 7 similar or identical to the features/components in FIG. 1 and FIG. 5 are designated with similar or the same reference numbers, and the details of those similar or the identical features/components are not repeated herein. The difference between the semiconductor device 70 in FIG. 7 and the semiconductor device 10 in FIG. 1 is the configurations of the second gate stack 230.

In the semiconductor device 70 shown in FIG. 7, the substrate 100 includes the first well region 110 (for example, n-type), the second well region 120 (for example, p-type), the third well region 130 (for example, p-type), the isolation structure 140, the drain region 160 (for example, n-type) and the source region 170 (for example, n-type). The semiconductor device 70 further includes a gate structure GS over the substrate 100. The gate structure GS is formed between the drain region 160 and the source region 170. The gate structure GS includes the first gate stack 210 and the second gate stack 230 that are electrically independent from each other. The first gate stack 210 is disposed over the first well region 110 and the third well region 130. In addition, the first gate stack 210 is disposed adjacent to the source region 170. The second gate stack 230 is disposed over the first well region 110 and adjacent to the drain region 160. The first gate stack 210 includes the first gate dielectric layer 211 and the first gate electrode layer 212. The first gate electrode layer 212 includes a main portion 212M and an extension portion 212E. In addition, the second gate stack 230 includes the second gate dielectric layer 231 and the second gate electrode layer 232, but the second gate electrode layer 232 does not have an extension portion. In addition, in this exemplary embodiment, there is no insulating layer, such as the insulating layer 202 in FIG. 1 and FIG. 2, over the substrate 100 of the semiconductor device 70. In addition, the thickness t1 of the first gate dielectric layer 211 is different from the thickness t2 of the second gate dielectric layer 231. For example, the thickness t1 of the first gate dielectric layer 211 is greater than the thickness t2 of the second gate dielectric layer 231. By providing gate dielectric layers with different thicknesses, the figure of merit (FOM) of the semiconductor device 70 can be effectively improved, and the switching power loss of the semiconductor device 70 can be reduced without affecting the breakdown voltage and leakage current when the semiconductor device 70 is turned off.

In addition, the gap 240 between the first gate electrode layer 212 and the second gate electrode layer 232 is also filled with one of more insulating materials, such as spacers (not shown in FIG. 7, but can be referred to the spacer 222 in FIG. 1 and FIG. 2) to electrically isolate the first gate stack 210 and the second gate stack 230. In this exemplary embodiment, the extension 212E of the first gate electrode layer 212 extends to the position over the insulating material in the gap 240, such as the position over the spacer 222 of FIG. 1 and FIG. 2, and further extends to the position over the second gate electrode layer 232. Details of the configurations, the materials and the manufacturing methods of the components in FIG. 7 can be referred to those in the above-mentioned descriptions referring to FIG. 1, FIG. 2 and FIG. 3A to FIG. 3L. Those contents will not be repeated herein.

Accordingly, in the semiconductor device 70 of the embodiment shown in FIG. 7, the first gate electrode layer 212 of the first gate stack 210 has an extension portion 212E. The vertical projection area A1 of the first gate electrode layer 212 on the substrate S partially overlaps with the vertical projection area of the second gate electrode layer 232 on the substrate S, such as an overlapping area Ao. In addition, unlike the insulating layer 202 on the substrate 100 shown in the semiconductor devices of FIG. 1 and FIG. 2, there is no insulating layer on the substrate 100 in the semiconductor device of FIG. 7, and the second gate electrode layer 232 of the second gate stack 230 does not have any extension portion that extends to the insulating layer.

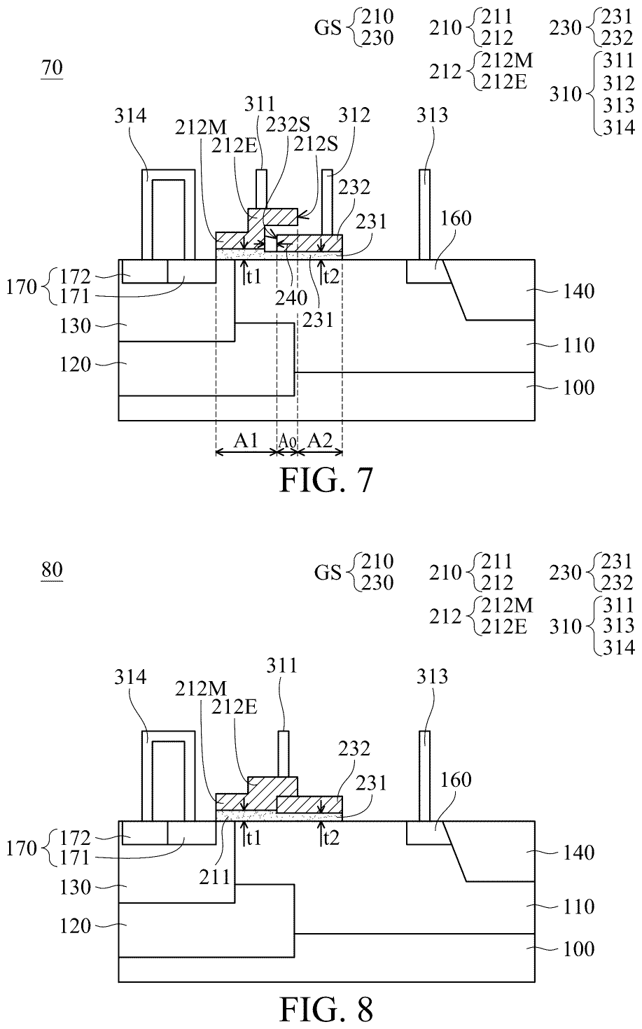

FIG. 8 is a schematic cross-sectional view of a semiconductor device at an intermediate manufacturing stage, in accordance with some embodiments of the present disclosure. The features/components in FIG. 8 similar or identical to the features/components in FIG. 1 are designated with similar or the same reference numbers. In addition, the details of those similar or the identical features/components are not repeated herein.

In the semiconductor device 80 shown in FIG. 8, a gate structure GS includes the first gate stack 210 and the second gate stack 230 that are arranged adjacent to each other. The first gate stack 210 is disposed over the first well region 110 and the third well region 130. In addition, the first gate stack 210 is disposed adjacent to the source region 170. The second gate stack 230 is disposed over the first well region 110 and adjacent to the drain region 160. The first gate stack 210 includes the first gate dielectric layer 211 and the first gate electrode layer 212. The first gate electrode layer 212 includes a main portion 212M and an extension portion 212E. In addition, the second gate stack 230 includes the second gate dielectric layer 231 and the second gate electrode layer 232, but the second gate electrode layer 232 does not have an extension portion. The extension portion 212E of the first gate electrode layer 212 extends to the position over the second gate electrode layer 232 and covers a portion of the top surface of the second gate electrode layer 232. In addition, there is no insulating layer, such as the insulating layer 202 in FIG. 1 and FIG. 2, over the substrate 100 of the semiconductor device 80. In this exemplary embodiment, the thickness t1 of the first gate dielectric layer 211 is different from the thickness t2 of the second gate dielectric layer 231. For example, the thickness t1 is greater than the thickness t2. Details of the configurations, the materials and the manufacturing methods of the components in FIG. 8 can be referred to those in the above-mentioned descriptions referring to FIG. 1, FIG. 2 and FIG. 3A to FIG. 3L. Those contents will not be repeated herein.

According to the aforementioned descriptions, the semiconductor devices and methods for forming the same, in accordance with some embodiments of the present disclosure, have many advantages. The gate structure of the semiconductor device that includes two gate dielectric layers with different thicknesses can effectively improve the figure of merit (FOM) of the semiconductor device without significantly affecting the breakdown voltage and leakage current when the semiconductor device is turned off. In addition, according to the gate structure of the semiconductor device of the embodiment, the charges of the capacitor between the gate and the drain (i.e., Qgd) can be greatly reduced, so that the semiconductor device has a faster switching speed, thereby reducing the switching power loss of the semiconductor device. In addition, although the method for forming the semiconductor device of the embodiments requires an additional photomask to define the gate stacks with gate dielectric layers of different thicknesses, it does not include complicated manufacturing processes and compatible with the existing processes. The method for forming the semiconductor device, in accordance with some embodiments of the present disclosure, can produce a semiconductor device with greatly improved performance such as the figure of merit (FOM).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, including:
a substrate;
a first well region in the substrate, wherein the first well region has a first conductivity type;
a second well region in the substrate and adjacent to the first well region, wherein the second well region has a second conductivity type;
a drain region in the first well region, wherein the drain region extends downward from a top surface of the first well region into the first well region, and the drain region has the first conductivity type;
a source region in the second well region, wherein the source region extends downward from a top surface of the second well region into the second well region, and the source region has the first conductivity type; and
a gate structure formed on the substrate and positioned between the source region and the drain region, wherein the gate structure comprises:
a first gate stack near the source region, wherein the first gate stack includes a first gate dielectric layer on the substrate and a first gate electrode layer on the first gate dielectric layer; and
a second gate stack near the drain region, wherein the second gate stack includes a second gate dielectric layer on the substrate and a second gate electrode layer on the second gate dielectric layer,
wherein a thickness of the first gate dielectric layer is different from a thickness of the second gate dielectric layer.

2. The semiconductor device as claimed in claim 1, wherein the thickness of the first gate dielectric layer is greater than the thickness of the second gate dielectric layer.

3. The semiconductor device as claimed in claim 1, wherein a thickness of the first gate electrode layer is different from a thickness of the second gate electrode layer.

4. The semiconductor device as claimed in claim 1, wherein a thickness of the first gate electrode layer is greater than a thickness of the second gate electrode layer.

5. The semiconductor device as claimed in claim 1, wherein the first gate electrode layer and the second gate electrode layer are laterally separated from each other by a gap, and the gap is correspondingly positioned above the first well region.

6. The semiconductor device as claimed in claim 1, wherein the first gate stack and the second gate stack are two electrically independent gate stacks.

7. The semiconductor device as claimed in claim 1, further including:
an insulating cap layer on the second gate stack, wherein the insulating cap layer covers the second gate electrode layer;
a spacer on sidewalls of the second gate electrode layer and sidewalls of the insulating cap layer.

8. The semiconductor device as claimed in claim 7, wherein the second gate electrode layer is electrically isolated from the first gate electrode layer by the spacer.

9. The semiconductor device as claimed in claim 7, wherein an extension portion of the first gate electrode layer is disposed above the spacer and covers the spacer.

10. The semiconductor device as claimed in claim 7, wherein an extension portion of the first gate electrode layer is disposed above the spacer and the insulating cap layer, and the extension portion covers the spacer and a portion of the insulating cap layer.

11. The semiconductor device as claimed in claim 7, wherein a thickness of the insulating cap layer is greater than a bottom width of the spacer.

12. The semiconductor device as claimed in claim 1, wherein there is a first distance between a bottom surface of the first gate electrode layer and a bottom surface of the second gate electrode layer, and an extension portion of the first gate electrode layer is higher than a top surface of the second gate electrode layer, wherein there is a second distance between a bottom surface of the extension portion and a top surface of a main portion of the second gate electrode layer, and the first distance is less than the second distance.

13. The semiconductor device as claimed in claim 1, wherein an extension portion of the first gate electrode layer is disposed above the second gate electrode layer, and the extension portion and the second gate electrode layer form an overlapping area.

14. The semiconductor device as claimed in claim 1, further comprising:
an insulating layer on the first well region, wherein the second gate electrode layer is disposed across the insulating layer,
wherein the second gate dielectric layer is adjacent to the insulating layer, and a thickness of the insulating layer is greater than a thickness of the second gate dielectric layer.

15. The semiconductor device as claimed in claim 1, wherein the thickness of the first gate dielectric layer and the thickness of the second gate dielectric layer differ by at least 20 angstrom or more.

16. A method for forming a semiconductor device, including:
providing a substrate;
forming a first well region and a second well region in the substrate, wherein the first well region has a first conductivity type and the second well region has a second conductivity type;
forming a drain region in the first well region and a source region in the second well region, wherein the drain region and the source region have the first conductivity type;
forming a gate structure over the substrate, wherein the gate structure is disposed between the source region and the drain region, and the gate structure comprises:
a first gate stack near the source region, wherein the first gate stack includes a first gate dielectric layer on the substrate and a first gate electrode layer on the first gate dielectric layer; and
a second gate stack near the drain region, wherein the second gate stack includes a second gate dielectric layer on the substrate and a second gate electrode layer on the second gate dielectric layer,
wherein a thickness of the first gate dielectric layer is different from a thickness of the second gate dielectric layer.

17. The method for forming a semiconductor device as claimed in claim 16, wherein the thickness of the first gate dielectric layer is greater than the thickness of the second gate dielectric layer.

18. The method for forming a semiconductor device as claimed in claim 16, wherein a thickness of the first gate electrode layer is different from a thickness of the second gate electrode layer.

19. The method for forming a semiconductor device as claimed in claim 16, wherein a thickness of the first gate electrode layer is greater than a thickness of the second gate electrode layer.

20. The method for forming a semiconductor device as claimed in claim 16, wherein the first gate electrode layer and the second gate electrode layer are laterally separated from each other by a gap, and the gap is correspondingly positioned above the first well region.

21. The method for forming a semiconductor device as claimed in claim 16, wherein the first gate stack and the second gate stack are two electrically independent gate stacks.

22. The method for forming a semiconductor device as claimed in claim 16, further comprising:
forming an insulating cap layer on the second gate stack, wherein the insulating cap layer covers a top surface of the second gate electrode layer; and
forming a spacer on sidewalls of the second gate electrode layer and sidewalls of the insulating cap layer,
wherein the second gate electrode layer and the first gate electrode layer are electrically isolated from each other by the spacer.

23. The method for forming a semiconductor device as claimed in claim 22, wherein a thickness of the insulating cap layer is greater than a bottom width of the spacer.

24. The method for forming a semiconductor device as claimed in claim 16, wherein there is a first distance between a bottom surface of the first gate electrode layer and a bottom surface of the second gate electrode layer, and an extension portion of the first gate electrode layer is higher than a top surface of the second gate electrode layer, wherein there is a second distance between a bottom surface of the extension portion and the top surface of the second gate electrode layer, and the first distance is less than the second distance.

25. The method for forming a semiconductor device as claimed in claim 16, wherein the first gate electrode layer has an extension portion that is disposed above the second gate electrode layer, and the extension portion and the second gate electrode layer form an overlapping area.

26. The method for forming a semiconductor device as claimed in claim 16, further comprising:
forming an insulating layer on the first well region, wherein the second gate electrode layer is disposed across the insulating layer,
wherein the second gate dielectric layer is adjacent to the insulating layer, and a thickness of the insulating layer is greater than a thickness of the second gate dielectric layer.

27. The method for forming a semiconductor device as claimed in claim 16, wherein the first gate structure is formed after the second gate stack is formed.

28. The method for forming a semiconductor device as claimed in claim 27, wherein after the second gate stack is formed, the method further comprises:
forming an insulating layer to cover a top surface and side surfaces of the second gate stack, and forming the first gate structure after the insulating layer is formed,
wherein the first gate structure is in contact with a portion of the insulating layer.
